(19) United States
(12) Patent Application Publication
(10) Pub. No.: US 2026/0239997 A1
(43) Pub. Date: Aug. 13, 2026

(54) SEMICONDUCTOR DEVICES WITH A SOLDER BRIDGE RESISTANT SUBSTRATE

(71) Applicant: TEXAS INSTRUMENTS INCORPORATED, DALLAS, TX (US)

(72) Inventors: GUANGXU LI, ALLEN, TX (US); JAIMAL WILLIAMSON, McKINNEY, TX (US); RAJEN MANICON MURUGAN, DALLAS, TX (US); SYLVESTER ANKAMAH-KUSI, McKINNEY, TX (US); JEFFREY SOLAS, ILOILO CITY (PH)

(21) Appl. No.: 19/047,874

(22) Filed: Feb. 7, 2025

(51) Int. Cl. H01L 23/00; H01L 21/48; H01L 21/56; H01L 23/31; H01L 23/498

(52) U.S. Cl. CPC H10W 70/05; H10W 70/69; H10W 72/07236; H10W 72/287; H10W 74/012; H10W 74/111; H10W 74/15; H10W 90/724

(57) ABSTRACT

A semiconductor device with a solder bridge resistant substrate. For example, a semiconductor package can include a substrate that can include a dielectric material and substrate pads. A cavity in the dielectric material can separate the substrate pads. A die is coupled to the substrate using a solder. The solder fills a portion of the cavity.

### TECHNICAL FIELD

This disclosure relates to semiconductor devices. More particularly, this disclosure relates to semiconductor devices with a solder bridge resistant substrate.

### BACKGROUND

A semiconductor device is an electronic component made from semiconductor material with controlled electrical conductivity. The term “semiconductor device” can refer to various types of electronic, including individual components, such as diodes, transistors, photonic devices and power devices, as well as integrated circuits (IC). An IC can incorporate multiple electronic components and/or circuits into a single chip. A chip, also known as a microchip, silicon chip, or die, is a piece of semiconductor material, usually silicon, on which the IC is fabricated. The IC can be further encapsulated in a package to form an IC package or semiconductor package. The package includes a packaging substrate, which is a material used to provide structural support and electrical connections. An embedded trace substrate (ETS) is a type of packaging substrate where conductive traces (wires) are embedded within a substrate material rather than being placed on a surface (as in traditional packaging substrates). A routable lead frame (RLF) substrate is another type of packaging substrate that uses a lead frame structure where leads are released from the substrate material, offering improved heat dissipation and mechanical stability compared to traditional lead frames, making such structures preferrable for high-power semiconductor devices. The die of the semiconductor device can be mounted on the package substrate and encapsulated in a molding, such as a plastic. The IC package is designed to be mounted on a printed circuit board (PCB) and connected to other components in an electronic system.

### SUMMARY

A first example relates to a semiconductor package that includes a substrate that can include a dielectric material and substrate pads. A cavity in the dielectric material separates the substrate pads. The package further includes a die that can be coupled to the substrate using a solder. The solder can fill a portion of the cavity.

A second example relates to a semiconductor package that includes a substrate that can include a dielectric material, substrate pads and a solder resist on a surface of the substrate between neighboring substrate pads of the substrate pads. A cavity in the dielectric material can separate the substrate pads. The package can include a die that can be coupled to the substrate using a solder. The solder can fill a portion of the cavity.

A third example relates to a method for fabricating a semiconductor package. The method can include forming a cavity in a dielectric material of a substrate between substrate pads of the substrate, positioning a die with respect to the substrate so that solder on the die is coaxial with respect to the substrate pads, reflowing the solder to cause the solder to partially fill the cavity and encapsulating the die and the substrate with a molding material to form the semiconductor package.

### BRIEF DESCRIPTION OF THE DRAWINGS

FIG. 1 illustrates a diagram of an example of a semiconductor device with a solder bridge resistant substrate.

FIG. 2 illustrates a diagram of another example of a semiconductor device with a solder bridge resistant substrate.

FIG. 3 illustrates a first stage of a method for forming a semiconductor device.

FIG. 4 illustrates a second stage of a method for forming the semiconductor package.

FIG. 5 illustrates a third stage of a method for forming the semiconductor package.

FIG. 6 illustrates a fourth stage of a method for forming the semiconductor package.

FIG. 7 illustrates a fifth stage of a method for forming the semiconductor package.

FIG. 8 illustrates a sixth stage of a method for forming the semiconductor package.

FIG. 9 illustrates a first stage of another method for forming a semiconductor device.

FIG. 10 illustrates a second stage of another method for forming the semiconductor package.

FIG. 11 illustrates a third stage of another method for forming the semiconductor package.

FIG. 12 illustrates a fourth stage of another method for forming the semiconductor package.

FIG. 13 illustrates a fifth stage of another method for forming the semiconductor package.

FIG. 14 illustrates a flowchart of an example method for forming one or more semiconductor devices according to the examples herein.

### DETAILED DESCRIPTION

This description relates to a semiconductor package with a solder bridge resistant substrate. Flip-chip technology is used in integrated circuit (IC) packaging, which allows for high-density interconnects and has improved electrical performance when compared to wire bonding technology. In flip-chip packaging, a die is mounted face down onto a substrate, with an active side (e.g., a side with circuitry and connections) facing the substrate. To connect the die to the substrate, an interconnect material or bonding material, such as solder bumps or copper (Cu) pillars can be used. The term “solder” refers to an alloy (e.g., a combination of tin and lead or lead-free alloys) that can be used for joining components in electronics and/or circuits. Cu pillars can be formed by depositing copper to create vertical interconnect structures, which can be capped with solder.

Solder bumps and Cu pillars are metallic connectors that can be used to join the die to the substrate during integrated circuit (IC) package fabrication. Solder bumps are spherical and can be deposited onto a die's connection points (e.g., metal contacts) and aligned with corresponding pads on the substrate. Cu pillars, in contrast, are fabricated by depositing copper onto the die's connection points to form vertical structures that can be capped with solder to facilitate bonding. During the fabrication process, the die is flipped upside down, and the Cu pillars or solder bumps are aligned with the substrate pads. When reflowed, a solder cap on the Cu pillars or the solder bumps creates an interconnection (e.g., mechanical and electrical connection) between the substrate and the die. However, the use of Cu pillars in high-density configurations, such as in semiconductor design that have constrained lead pitches (e.g., in routable lead frame (RLF) and embedded trace substrate (ETS) semiconductor designs), can introduce mechanical stress to an interlayer dielectric (ILD), potentially damaging the ILD (e.g., causing cracks). The ILD is an insulating layer located between metal layers in the substrate. Cracks or defects in the ILD can compromise a reliability of a final packaged semiconductor device.

In some examples, solder bars are preferred over solder bumps for use in high-density configurations. Solders bars can provide a larger contact area between the die and the substrate for current flow when compared to a single spherical solder bump. Solder bars differ in shape and volume from solder bumps. Rather than being small, spherical connectors, solder bars are elongated, long oval-shaped structures. Solder bars use a larger amount of solder compared to solder bumps. Thus, the increased solder material in solder bars can elevate a risk of solder bridging during thermal soldering (e.g., reflow).

Accordingly, the use of solders bars in high-density configurations can result in solder bridging during reflows. For example, during reflow (where a solder melts to create a connection), the solder bars collapse due to gravity and a heating process. This collapse can cause the solder to spread out, in some instances, leading to solder bridging. Solder bridging is a defect that occurs when molten solder unintentionally connects two or more adjacent pads on the substrate. Thus, if the solder melts and spreads too much during the reflow process, the melted solder can unintentionally connect two adjacent pads on the substrate. Solder bridging can lead to malfunctioning of the die because this defect causes electrical shorts between the pads of the die. Because high-density semiconductor designs (e.g., RLF and ETS designs) have small lead pitches, where a spacing between pads is constrained (e.g., tight), this increases a likelihood of solder spreading and creating unwanted connections (solder bridge defects) in such semiconductor design configurations.

According to one or more examples herein, a semiconductor device is disclosed with a solder bridge resistant substrate. The semiconductor device includes a substrate. The substrate includes a dielectric material and substrate pads. The dielectric material separates the substrate pads. A cavity in the dielectric material separates the substrate pads. The semiconductor device includes a die that includes die connections. The die can be coupled to the substrate using a solder. The solder forms a bond between the die connections and the substrate pads. In some examples, the solder fills a portion of the cavity. In yet some examples, the substrate includes a solder resist on a surface of the substrate between neighboring substrate pads of the substrate pads. The solder resist protrudes above a surface of the substrate. The solder resist and the cavity prevent the solder from spreading across the surface of the substrate from a substrate pad to a neighboring substrate pad of the substrate pads during a reflow of the solder. Thus, the solder resist and the cavity can prevent solder bridging during reflow and thus fabrication of the semiconductor device.

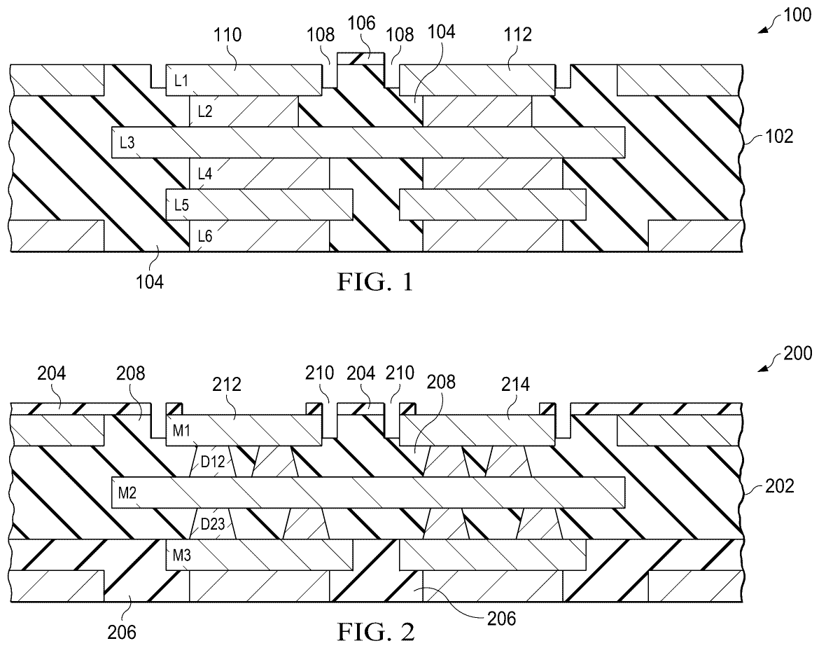

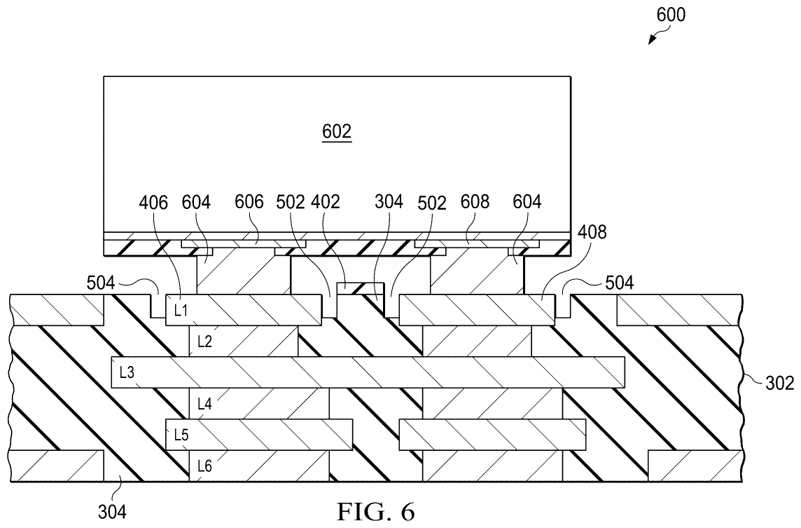

FIG. 1 illustrates a diagram of an example of a semiconductor device 100 with a substrate 102 that is configured to be solder bridge resistant (e.g., during a soldering process) and thus can be referred to as a solder bridge resistant substrate. The substrate and one or more dies, such as disclosed herein, can be packaged to provide the semiconductor device 100. For example, the substrate 102 and a die (e.g., a die 602 of FIG. 6) can be packaged using a packaging technology, such as flip-chip packaging, which can include using solder (e.g., solder bars) to form electrical and mechanical connections between the substrate 102 and the die. The substrate 102 can be an RLF substrate.

The substrate 102 is a multi-layer substrate with metal layers L1-L6 and a dielectric material 104, in some instances, an Ajinomoto build-up film (ABF), as shown in FIG. 1. The dielectric material 104 can be used to isolate one or more metal layers of the metal layers L1-L6 to allow for controlled routing of signal through vias or other interconnects in the substrate 102 (not shown). The metal layers L1-L6 can be used to form electrical interconnections between the die (when attached) and an external package (e.g., a flip-chip package) and thus some of the metal layers L1-L6 can be designated for signal routing.

The substrate 102 includes a solder resist 106. The solder resist 106 protrudes above a surface of the substrate 102. The solder resist 106 is a protective layer on a surface of the substrate 102 that is used to prevent solder from spreading into unintended areas of the surface of the substrate 102, for example, during reflow. The solder resist 106 can be an epoxy-based material and can be applied to the surface of the substrate 102 to curtail solder bridging. The solder resist 106 is used to control solder flow between neighboring (or inner) pads and thus acts as a barrier during the reflow of the solder between the neighboring pads, such as pads 110-112 of the substrate 102, to prevent solder bridging. The pads 110-112 can be referred to as substrate pads 110-112. The solder resist 106 can be added between inner pads (also known as leads) of the substrate 102, where a bonding material (e.g., a solder bar) can be attached. The solder resist 106 acts as a barrier between the pads 110-112 of the substrate 102 to prevent solder from spreading beyond designated areas (e.g., to other neighboring pads) during a reflow of the solder (e.g., heating of the solder).

The solder resist 106 can have a predetermined thickness (referred to as a solder resist thickness). In some examples, the solder resist 106 is about 15±5 microns (μm) thick, or about 10 μm to about 20 μm, which can be referred to as a solder resist thickness range. If the solder resist thickness exceeds an upper bound of the solder resist thickness range (e.g., about 20 μm), a separation between the die and a solder resist interface can become too small, which can lead to mold voids. A solder resist interface refers to a separation or clearance between the solder resist 106 and the die (or bonding material) when the die is mounted onto the substrate 102. Thus, if the solder resist is too thick (e.g., exceeds the upper bound of the solder resist thickness range), a gap between the die and the solder resist 106 is reduced, which can trap air or create mold voids (e.g., during an encapsulation process). In some instances, if the solder resist is too thin (e.g., is below a lower bound of the solder resist thickness range, such as about 10 μm), solder bridging can occur between adjacent pads 110-112, for example, during reflow.

In some examples, a cavity 108 can be formed in the dielectric material 104 to separate the pads 110-112. The cavity 108 can be formed in a non-metal layer (the dielectric material 104) of the substrate 102. Each cavity 108 can be formed (located) between inner pads, such as between the pads 110-112 of the substrate 102, as shown in FIG. 1. In some examples, the cavity 108 is positioned (located) between sides of neighboring substrate pads 110-112. In some scenarios, the cavity 108 can extend around all sides of a respective pad, such as one of the pads 110-112. In yet some examples, a respective cavity extends on sides of a pad that can neighbor one or more other pads of the substrate 102. Each cavity 108 within the substrate 102 can be located in the dielectric material 104 around a respective edge portion of the pads 110-112. For example, the cavity 108 can be located in the dielectric material 104 such that each cavity 108 is adjacent to the edge portion (e.g., a side) of the pads 110-112. The dielectric material 104 separates the pads 110-112, as shown in FIG. 1. The cavity 108 can be located (e.g., partially located) within the dielectric material 104 between the pads 110-112.

The cavity 108 and the solder resist 106 can function together to curtail (e.g., reduce) solder spreading during reflow. The cavity 108 also functions as a crack arrest structure, slowing down any potential cracking in the substrate 102 and/or solder from propagating. For example, the substrate 102 and/or the solder can experience mechanical stress or undergo thermal cycling (e.g., during use), which can result in cracks forming in the substrate 102 and/or the solder. Because the substrate 102 has the cavity 108 cracks can be curtailed (or slowed down) in the substrate 102 and/or the solder and thus a reliability and lifespan of the semiconductor device 100 can be extended.

Accordingly, inclusion of the solder resist 106 and, in some instances, also the cavity 108 in the substrate 102 curtails (in some instances eliminates) solder spreading during reflow and thus can prevent solder bridging. The solder resist 106 acts as a barrier between neighboring pads (e.g., the pads 110-112), while the cavity 108 between these neighboring pads further curtails solder flow acting as a solder overflow reservoir. The cavity 108 also serves as a crack arrest structure by redistributing a stress experienced by the substrate 102 and/or the solder to prevent crack propagation, which improves a reliability and lifespan of the semiconductor device 100.

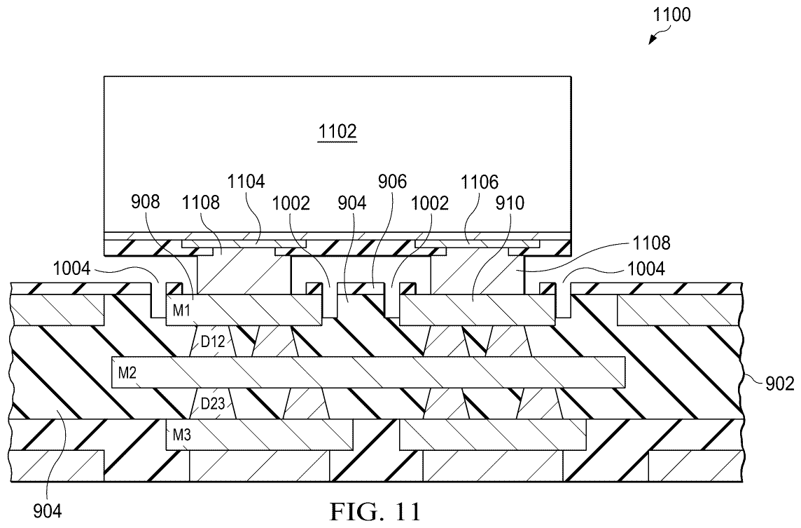

FIG. 2 illustrates a diagram of another example of a semiconductor device 200 with a substrate 202 that is configured to be solder bridge resistant (e.g., during a soldering process) and thus can be referred to as a solder bridge resistant substrate. The substrate and one or more dies, such as disclosed herein, can be packaged to provide the semiconductor device 200. For example, the substrate 202 and a die (e.g., a die 1102 of FIG. 11) can be packaged using a packaging technology, such as flip-chip packaging, which can involve using solder (e.g., solder bars) to form electrical and mechanical connections between the substrate 202 and the die. The substrate 202 can be an ETS substrate.

The substrate 202 is a multi-layer substrate. The substrate 202 includes a solder resist 204. The solder resist 204 can be located at a top surface of the substrate 202. The solder resist 204 protrudes above the surface of the substrate 202. The substrate 202 can include additional solder resist materials at one or more other layers of the substrate. For example, the substrate 202 can include a solder resist material 206, as shown in FIG. 2. The solder resist 204 (similar to the solder resist 106 as shown in FIG. 1) functions to prevent solder from flowing into unwanted areas of the substrate 202, for example, during reflow.

For semiconductor devices with an ETS type substrate (e.g., the substrate 202) no additional steps are needed during fabrication to add a solder resist material, such as in semiconductor devices with an RLF type substrate (e.g., the semiconductor device 100 of FIG. 1). This is because the substrate 202 has the solder resist 204 at a surface. The solder resist 204 can be an epoxy-based material. The solder resist 204 can be used to control solder flow to prevent solder bridging during reflow.

The substrate 202 includes a dielectric material 208. In some examples, the dielectric material 208 is a prepreg material. The prepreg material is a composite material made from a matrix of resin and reinforcement fibers (e.g., fiberglass) that has been partially cured. The dielectric material 208 can be used to bond layers of the multi-layer substrate (the substrate 202) together during a lamination process. The substrate 202 can also include metal layers M1-M3 and inter-layer metal connectors D12 and D23.

The inter-layer metal connector D12 can be located between metal layers M1 and M2, whereas the inter-layer metal connectors D23 can be located between metal layers M2 and M3, as shown in FIG. 2. The dielectric material 208 can be used to isolate one or more metal layers of the metal layers M1-M3 to allow for controlled routing of signals through the interconnects D12 and D23 in the substrate 202. The metal layers M1-M3 can be used to form electrical interconnections between the die (when attached) and an external package (e.g., a flip-chip package) and thus some of the metal layers M1-M3 can be designated for signal routing.

In some examples, a cavity 210 can be formed within the dielectric material 208. In some examples, the cavity 210 can be formed in the solder resist 204 and the dielectric material 208. Each cavity 210 can be formed (positioned) between inner pads (traces) of the substrate 102, such as between pads 212-214 of the substrate 202, as shown in FIG. 2. The pads 212-214 can be referred to as substrate pads 212-214.

In some examples, the cavity 210 is positioned (located) between sides of neighboring substrate pads 212-214. In some scenarios, the cavity 210 can extend around sides of a respective pad, such as one of the substrate pads 212-214. In yet some examples, a respective cavity extends on sides of a pad that can neighbor one or more other pads of the substrate 202. Each cavity 210 of the substrate 202 can be located in the dielectric material 208 and the solder resist 204 around a respective edge portion of the pads 212-214. For example, the cavity 210 can be located in the dielectric material 208 such that the cavity 210 is adjacent to the edge portion of the pads 212-214. The dielectric material 208 separates the substrate pads 212-214, as shown in FIG. 2. The cavity 210 can be located (e.g., partially located) within the dielectric material 208 between the pads 212-214.

The cavity 210 and the solder resist 204 can function together to curtail solder spreading during the soldering process. Thus, in some examples, the solder can fill a portion of the cavity 210. The cavity 210 also functions as a crack arrest structure, slowing down any cracking in the substrate 202 and/or solder from propagating. For example, the substrate 202 and/or the solder can experience mechanical stress or undergo thermal cycling (e.g., during use), which can result in cracks forming in the substrate 202 and/or the solder. Because the substrate 202 has the cavity 210 cracks can be curtailed (or impeded) in the substrate 202 and/or solder and thus a reliability and lifespan of the semiconductor device 200 can be extended.

Accordingly, leveraging the solder resist 204 and, in some instances, also the cavity 210 in the substrate 202 curtails (in some instances eliminates) solder spreading during reflow, which prevents solder bridging. The solder resist 204 acts as a barrier between neighboring pads (e.g., the pads 212-214), while the cavity 210 between these neighboring pads acts as a solder overflow reservoir. The cavity 210 also acts as a crack arrest structure by redistributing a stress experienced by the substrate 202 and/or the solder to prevent crack propagation, which improves a reliability and lifespan of the semiconductor device 200.

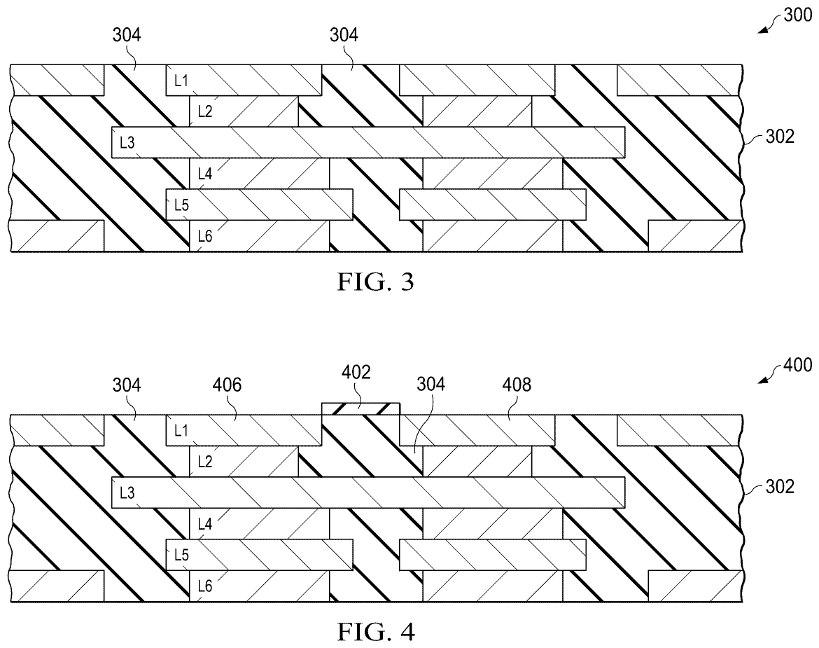

FIGS. 3-8 illustrate stages of a method for fabricating (e.g., assembling) a semiconductor package with a solder bridge resistant substrate. As illustrated in FIG. 3, at 300, in a first stage, a substrate 302 (or substrate film) is prepared (produced). In some examples, at the first stage 300, the substrate 302 can be provided. The substrate 302 includes metal layers L1-L6 and a dielectric material 304. The dielectric material 304 can correspond to the dielectric material 104 of FIG. 1. Thus, in some instances, the dielectric material 304 is an ABF. In yet some examples, the substrate 202 is an RLF.

At a second stage, at 400, as illustrated in FIG. 4, a solder resist 402 is formed on the substrate 302. For example, the solder resist 402 can be formed (deposited) on a (top) surface of the substrate 302. The solder resist 402 protrudes above a surface of the substrate 302. The solder resist 402 can be an epoxy-based material. The solder resist 402 is used to control solder flow during a reflow. The solder resist 402 can be used to curtail movement of solder during the reflow to prevent solder bridging. The solder resist 402 can be deposited over a portion of dielectric material 304 of the substrate 302 that resides between adjacent (or neighboring) pads 406-408 of the substrate 302, as shown in FIG. 4. The solder resist 402 can cover a region between the pads 406-408 that limits solder flow from a pad to a neighboring pad during reflow.

Thus, the solder resist 402 is formed on the top surface of the substrate 302 to cover a surface of the substrate 302 that is exposed and is located between the pads 406-408. The solder resist 402 does not cover the surface of the pads 406-408, thereby leaving a metal surface of the pads 406-408 exposed for bonding (e.g., during the soldering process). In yet some examples, the pads 406-408 can correspond to the pads 110-112 of FIG. 1. The pads 406-408 can be metal regions that are formed within a first (or top) metal layer L1 of the metal layers L1-L6 of the substrate 302

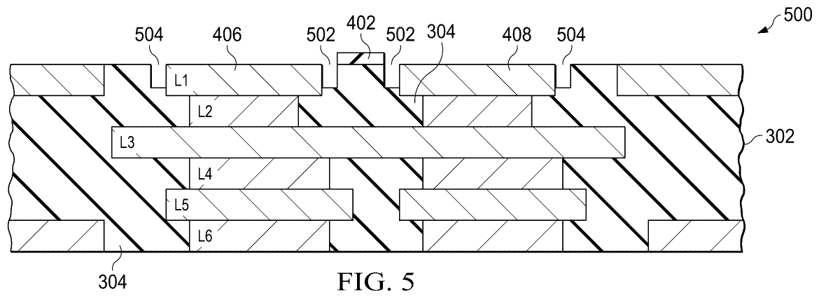

At a third stage, at 500, as illustrated in FIG. 5, cavities 502-504 can be formed within the dielectric material 304. In some examples, the substrate 302, at the third stage, can correspond to the substrate 102 of FIG. 1 and thus can be referred to as a solder bridge resistant substrate. The cavities 502-504 can be formed using laser ablation or plasma etching. For example, the cavities 502-504 can be formed around the pads 406-408 (e.g., on each side of the pads 406-408), as shown in FIG. 5. The cavities 502 can be formed by removing a first portion of the dielectric material 304 between the pads 406-408 and thus around a first edge portion of the pads 406-408. The cavities 504 can be formed by removing a second portion of the dielectric material 304 around a second edge portion of the pads 406-408, as shown in FIG. 5. In some examples, the cavities 502 are formed between sides of the pads 406-408 or next to a respective side of the pads 406-408. In some scenarios, the cavity 502 can extend around all sides of a respective pad, such as one of the pads 406-408. In such scenarios, the cavity 504 can be omitted. In yet some examples, a respective cavity extends on sides of a pad that neighbors corresponding substrate pads. Thus, in some examples, the cavity 502 extends on a first side of a pad (e.g., the pad 406) and the cavity 504 extends on a second side of the substrate pad. The first side of the pad can neighbor a side of another pad (e.g., the pad 408).

The cavities 502 between the pads 406-408 are used to reduce a spread of solder (e.g., solder paste) during the reflow thus curtailing solder bridging. The cavities 504 can also be used to reduce solder spread during the reflow and thus can also contribute to curtailing solder bridging. In addition to controlling solder flow and preventing solder bridging, the cavities 502-504 can function as crack arrest structures within the substrate 302. The cavities 502-504, formed in the dielectric material 304, around and/or between the substrate pads 406-408, can curtail (e.g., halt) crack from propagating in the substrate 302 and/or the solder that can develop due to thermal cycling or mechanical stress experienced by the substrate 302 and/or the solder.

At a fourth stage, at 600, as illustrated in FIG. 6, a die 602 can be positioned with respect to the substrate 302 so that die connections 606-608 of the die 602 align with the pads 406-408, which can be referred to as substrate pads 406-408. The die 602 can include solder bars 604. The die 602 can be flipped (or inverted) so that the die connections 606-608, along with the solder bars 604, are placed onto (e.g., directly onto) corresponding substrate pads 406-408. The solder bars 604 (and thus the die connections 606-608) can be coaxial with respect to the substrate pads 406-408 in response to the die 602 being flipped and aligned with the substrate 302. In some instances, the solder bars 604 on the die connections 606-608 can rest on a top surface of the substrate pads 406-408.

The die connections 606-608 on the die 602 provide electrical connectivity between the die 602 and external circuitry (e.g., the substrate 302). The solder bars 604 can be applied to the die connections 606-608, such as during fabrication of the substrate 302 (or after fabrication of the substrate 302). In yet some examples, the solder bars 604 are formed on corresponding die connections 606-608 during the method described herein with respect to FIGS. 3-8. The solder bars 604 correspond to a solder deposit formed on the die connections 606-608 that can be used to form an electrical and mechanical connection between the substrate pads 406-408 and the die connections 606-608. For example, the solder bars 604 can be formed of a conductive material (e.g., tin-lead or lead-free solder alloy). A solder bar 604 can be placed on each die connection 606-608 to allow for contact between the die connections 606-608 and corresponding substrate pads 406-408.

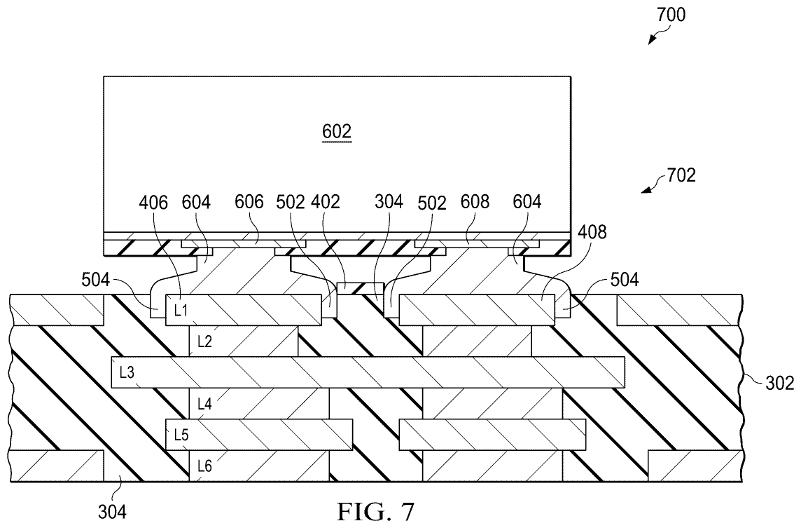

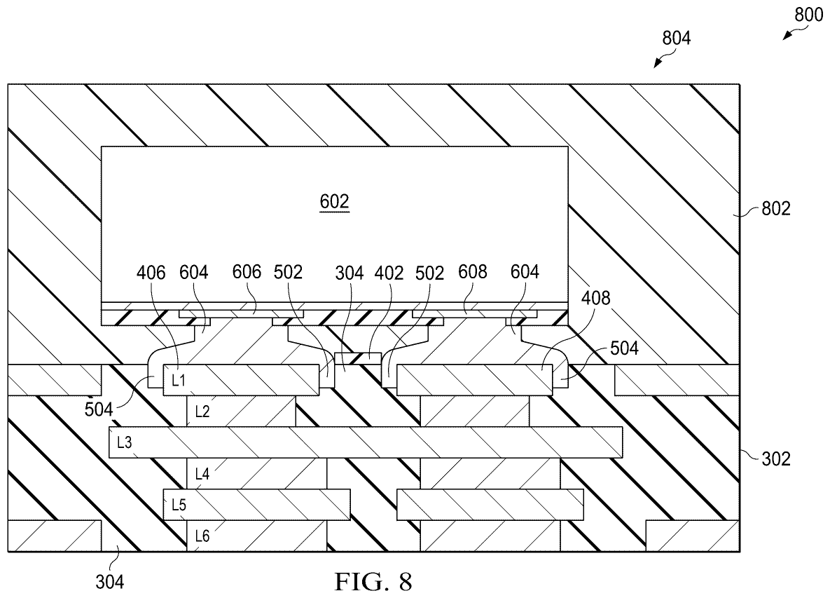

At a fifth stage, at 700, as illustrated in FIG. 7, a reflow can be applied to the die 602 once positioned with respect to the substrate 302 to provide a device assembly 702. For example, once the die 602 is in position, with the solder bars 604 coaxial with respect to the substrate pads 406-408, and in some instances resting on the substrate pads 406-408, a reflow process can be applied. During reflow, heat can be applied to melt the solder bars 604 and thus the solder bars 604 can become liquid solder. As the solder bars 604 melt, the liquid solder flows onto the substrate pads 406-408. Once the liquid solder has cooled (solidified), the solidified solder forms a bond between the die connections 606-608 and the substrate pads 406-408. The term “solidified solder” refers to a bonding material, such as solder after the bonding material has been melted during reflow and then cooled to form a solid bond between die connections and substrate pads.

The bond forms (or creates) an electrical and mechanical connection between the die connections 606-608 and the substrate pads 406-408. The solder resist 402, deposited on the surface of the substrate 302 between the substrate pads 406-408 controls a flow of the liquid solder (e.g., solder flow) during reflow. The solder resist 402 acts as a barrier that prevents the liquid solder from flowing into unwanted areas (e.g., a neighboring substrate pad from a nearby substrate pad) to prevent solder bridging. By curtailing the spread of solder during reflow (e.g., heating), the solder resist 402 allows for the bonds (or connections) between the die connections 606-608 and substrate pads 406-408 to remain isolated from each other, as shown in FIG. 8.

In yet some examples, the cavities 502-504 formed between and/or around the substrate pads 406-408 can also curtail a risk of solder bridging during reflow. For example, as the liquid solder flows, during the reflow process, any excess solder of the liquid solder that flows beyond a contact area between the die connections 606-608 and the substrate pads 406-408 flows into the cavities 502-504 formed between and/or around the substrate pads 406-408 to fill the cavities 502-504. The contact area refers to a metal surface of the substrate pads 406-408.

The cavities 502-504 can be used to control a solder flow of the liquid solder to prevent the liquid solder during reflow from spreading beyond intended areas (e.g., the contact area), such as to a neighboring substrate pad. Thus, the cavities 502-504 act as a physical barrier to trap any excess solder to prevent the excess solder from creating unintended electrical connections between adjacent substrate pads, such as between the substrate pads 406-408. In some examples, a solder (the solidified solder) fills a portion of the cavities 502-504.

At a sixth stage, at 800, as illustrated in FIG. 8, the device assembly 702 can be molded using a molding compound 802 to provide a semiconductor device 804, as shown in FIG. 8. In some examples, the semiconductor device 804 corresponds to the semiconductor device 100 of FIG. 1.

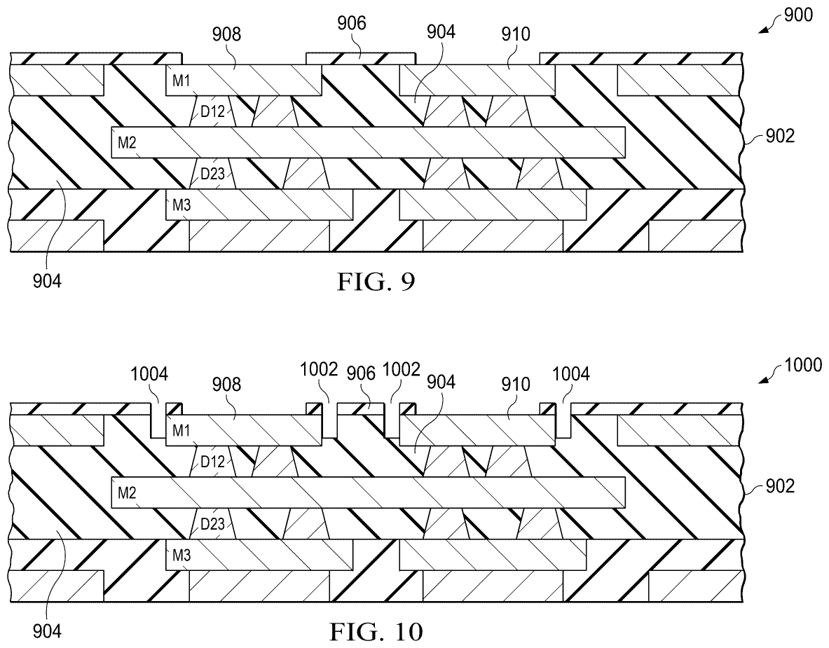

FIGS. 9-13 illustrate stages of yet another method for fabricating (e.g., assembling) a semiconductor package with a solder bridge resistant substrate. As illustrated in FIG. 9, at 900, in a first stage, a substrate 902 (or substrate film) is prepared (produced). In some examples, at the first stage 900, the substrate 902 can be provided. The substrate 902 includes metal layers M1-M3, inter-layer metal connectors D12 and D23, a dielectric material 904 and a solder resist 906. The dielectric material 904 can correspond to the dielectric material 208 of FIG. 2 and the solder resist 906 can correspond to the solder resist 204 of FIG. 2. The substrate 202 can be prepared with the solder resist 204. In yet some examples, the substrate 202 is an ETS.

As illustrated in FIG. 9, the solder resist 906 can be located on a (top) surface of the substrate 902. The solder resist 906 protrudes above a surface of the substrate 902. The solder resist 906 can be an epoxy-based material. The solder resist 906 can be used to control solder flow, such as during reflow. The solder resist 906 can be used to curtail (e.g., limit) the movement of solder during reflow to reduce solder bridging. The solder resist 906 can cover a surface region between pads 908-910 of the substrate 902 to limit solder flow during reflow. Thus, the solder resist 906 can be located on the top surface of the substrate 902 that is exposed and is located between the pads 908-910. The solder resist 906 does not cover the surface of the pads 908-910 (in some instances can partially cover the surface of the pads 908-910), thereby leaving a metal surface of the pads 908-910 exposed for bonding (e.g., during reflow). In yet some examples, the pads 908-910 can correspond to the pads 212-214 of FIG. 2. The pads 908-910 can be metal regions that are formed within a first (or top) metal layer M1 of the metal layers M1-M3 of the substrate 902.

At a second stage, at 1000, as illustrated in FIG. 10, cavities 1002-1004 can be formed in the dielectric material 904. In some examples, the substrate 902, at the second stage, can correspond to the substrate 202 of FIG. 2 and thus can be referred to as a solder bridge resistant substrate. The cavities 1002-1004 can be formed using laser ablation or plasma etching. For example, the cavities 1002-1004 can be formed around the pads 908-910 (e.g., on each side of the pads 908-910), as shown in FIG. 10. The cavities 1002 can be formed by removing a first portion of the dielectric material 904 between the pads 908-910 and around a first edge portion of the pads 908-910. The cavities 1004 can be formed by removing a second portion of the dielectric material 904 around a second edge portion of the pads 908-910. In some examples, the cavities 1002 are formed between sides of the pads 908-910 or next to a respective side of the pads 908-910. In some scenarios, the cavity 1002 can extend around sides of a respective pad, such as one of the pads 908-910. In such scenarios, the cavity 1004 can be omitted. In yet some examples, a respective cavity extends on sides of a pad that neighbors corresponding substrate pads. Thus, in some examples, the cavity 1002 extends on a first side of a pad (e.g., the pad 908) and the cavity 1004 extends on a second side of the substrate pad. The first side of the pad can neighbor a side of another pad (e.g., the pad 910).

The cavities 1002 between the pads 908-910 are used to reduce a spread of solder (e.g., solder paste) during reflow and thus curtail solder bridging. The cavities 1004 can also be used to reduce solder spread during reflow and thus can contribute to curtailing solder bridging. In addition to controlling solder flow and preventing solder bridging, the cavities 1002-1004 can function as crack arrest structures within the substrate 902. The cavities 1002-1004, formed in the dielectric material 904, around and/or between the substrate pads 908-910, can curtail (e.g., halt) cracks from propagating in the substrate 902 and/or solder that can develop due to thermal cycling or mechanical stress experienced by the substrate 902 and/or the solder.

At a third stage, at 1100, as illustrated in FIG. 11, a die 1102 can be positioned with respect to the substrate 902 so that die connections 1104-1106 of the die 1102 align with the pads 908-910, which can be referred to as substrate pads 908-910. The die 1102 can include solder bars 1108. The die 1102 can be flipped (or inverted) so that the die connections 1104-1106, along with the solder bars 1108, are placed onto (e.g., directly onto) corresponding substrate pads 908-910. The solder bars 1108 (and thus the die connections 1104-1106) can be coaxial with respect to the substrate pads 908-910 in response to the die 1102 being flipped and aligned with the substrate 902. In some examples, the solder bars 1108 can rest on a top surface of the substrate pads 908-910.

The die connections 1104-1106 on the die 1102 provide electrical connectivity between the die 1102 and external circuitry (e.g., the substrate 902). The solder bars 1108 can be applied to the die connections 1104-1106, such as during fabrication of the substrate 902 (or after fabrication of the substrate 902). In yet some examples, the solder bars 1108 are formed on corresponding die connections 1104-1106 during the method described herein with respect to FIGS. 9-13. The solder bars 1108 correspond to a solder deposit formed on the die connections 1104-1106 that can be used to form an electrical and mechanical connection between the substrate pads 908-910 and the die connections 1104-1106. For example, the solder bars 1108 can be formed of a conductive material (e.g., tin-lead or lead-free solder alloy) The solder bars 1108 can be applied to the die connections 1104-1106. A solder bar 1108 can be placed on each die connection 1104-1106 to allow for contact between the die connections 1104-1106 and the corresponding substrate pads 908-910.

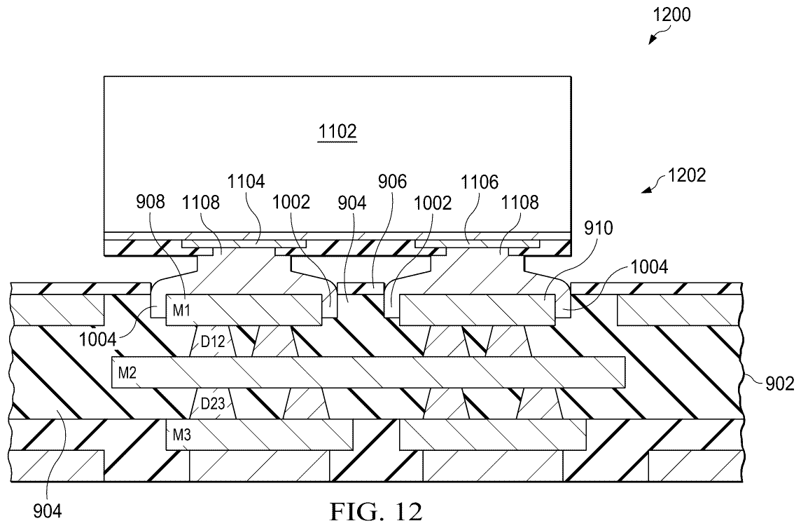

At a fourth stage, at 1200, as illustrated in FIG. 12, reflow can be applied to the die 1102 once positioned with respect to the substrate 902 to provide a device assembly 1202. For example, once the die 1102 is in position, with the solder bars 1108 coaxial with respect to the substrate pads 908-910, and in some instances resting on the substrate pads 908-910, a reflow process can be applied. During reflow, heat can be applied to melt the solder bars 1108 and thus the solder bars 1108 can become liquid solder. As the solder bars 1108 melt, the liquid solder flows onto the substrate pads 908-910.

Once the liquid solder has cooled (solidified), the solidified liquid solder forms a bond between the die connections 1104-1106 and the substrate pads 908-910. The bond forms (or creates) an electrical and mechanical connection between the die connections 1104-1106 and the substrate pads 908-910. The solder resist 906, deposited on the surface of the substrate 902 between the substrate pads 908-910, controls a flow of the liquid solder (e.g., solder flow) during reflow. The solder resist 906 acts as a barrier that prevents the liquid solder from flowing into unwanted areas (e.g., a neighboring substrate pad from a nearby substrate pad) to prevent solder bridging. By curtailing the spread of solder during reflow, the solder resist 906 allows for the bonds (or connections) between the die connections 1104-1106 and substrate pads 908-910 to remain isolated from each other, as shown in FIG. 12.

In yet some examples, the cavities 1002-1004 formed between and/or around the substrate pads 908-910 can also curtail a risk of solder bridging during reflow. For example, as the liquid solder flows, during reflow, excess solder of the liquid solder that flows beyond a contact area between the die connections 1104-1106 and the substrate pads 908-910 flows into the cavities 1002-1004 formed between and/or around the substrate pads 908-910 to fill the cavities 1002-1004. The contact area refers to a metal surface of the substrate pads 908-910.

The cavities 1002-1004 can be used to control a solder flow of the liquid solder to prevent the liquid solder during reflow from spreading beyond intended areas (e.g., the contact area), such as to a neighboring substrate pad. Thus, the cavities 1002-1004 act as a physical barrier to trap excess solder to prevent the excess solder from creating unintended electrical connections between adjacent substrate pads, such as between the substrate pads 908-910. In some examples, a solder (the solidified solder) fills a portion of the cavities 1002-1004.

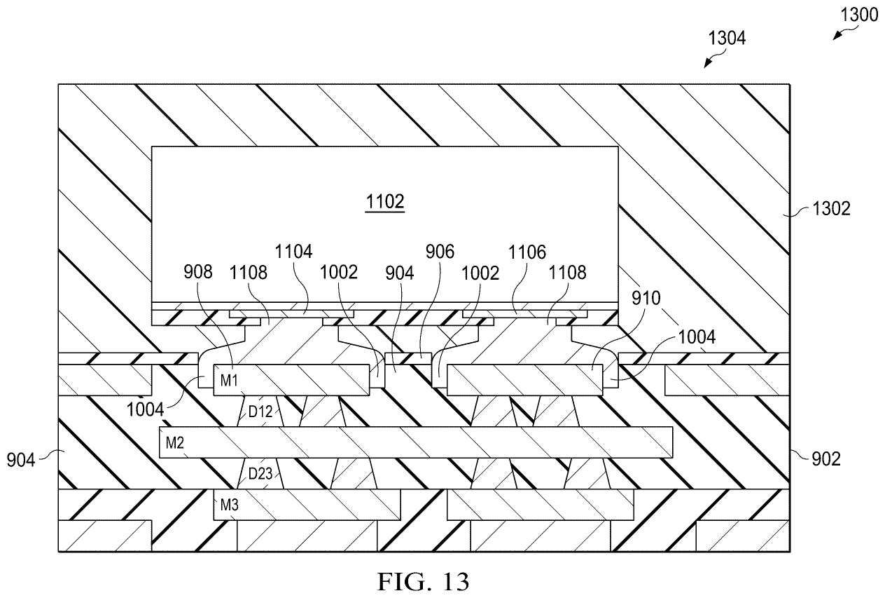

At a fifth stage, at 1300, as illustrated in FIG. 13, the device assembly 1202 can be molded using a molding compound 1302 to provide a semiconductor device 1304, as shown in FIG. 13. In some examples, the semiconductor device 1304 corresponds to the semiconductor device 200 of FIG. 2.

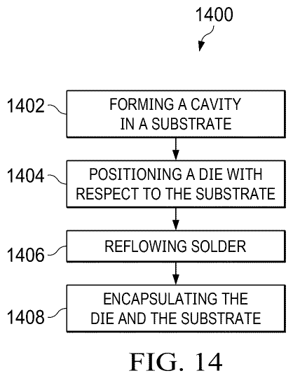

FIG. 14 illustrates a flowchart of an example method 1400 for forming a semiconductor device. The method 1400 could be employed, for example, to form the semiconductor device 100 of FIG. 1, the semiconductor device 200 of FIG. 2, the semiconductor device 804 of FIG. 8 and/or the semiconductor device 1304 of FIG. 13.

The method 1400 can begin at 1402 at which one or more cavities (e.g., the cavities 108 of FIG. 1, the cavities 210 of FIG. 2, the cavities 502 of FIG. 5 or the cavities 1002 of FIG. 10) are formed between inner substrate pads (e.g., the substrate pads 110-112 of FIG. 1, the substrate pads 210-212 of FIG. 2, the substrate pads 406-408 of FIG. 4 or the substrate pads 908-910) of a substrate, such as the substrate 102 of FIG. 1, the substrate 202 of FIG. 2, the substrate 302 of FIG. 3 or the substrate 902 of FIG. 9. The substrate can include a solder resist, such as the solder resist 106 of FIG. 1, the solder resist 204 of FIG. 2, the solder resist 402 of FIG. 4 or the solder resist 906 of FIG. 9. For example, each cavity can be formed in a dielectric material of the substrate, such as the dielectric material 104 of FIG. 1 (e.g., ABF), the dielectric material 208 of FIG. 2 (e.g., prepreg material), the dielectric material 304 of FIG. 3 or the dielectric material 904 of FIG. 9.

At 1404, a die (e.g., the die 602 of FIG. 6 or the die 1102 of FIG. 11) is positioned with respect to the substrate so that solder on the die is coaxial with respect to the substrate pads. In some examples, the solder is the solder bars 604 of FIG. 6 or the solder bars 1108 of FIG. 11. At 1406, the solder is reflowed (e.g., heated) to cause the solder to partially fill the one or more cavities. Thus, the solder fills a portion of the one or more cavities.

In some examples, the solder resist is formed (or deposited) on a surface of the substrate between neighboring substrate pads of the substrate pads. The solder resist prevents the solder from spreading across the surface of the substrate from a substrate pad to a neighboring substrate pad during reflow and thus functions to curtail solder bridging.

At 1408, the die and the substrate can be encapsulated with a molding material (e.g., the molding compound 802 of FIG. 8 or the molding compound 1302 of FIG. 13) to form the semiconductor device (e.g., a semiconductor package).

In this description, unless otherwise stated, “about,” “approximately” or “substantially” preceding a parameter means being within +/−10 percent of that parameter. Modifications are possible in the described embodiments and other embodiments are possible, within the scope of the claims.

What is claimed is:

1. A semiconductor package comprising:
a substrate comprising a dielectric material and substrate pads, wherein a cavity in the dielectric material separates the substrate pads; and
a die being coupled to the substrate using a solder, wherein the solder fills a portion of the cavity.

2. The semiconductor package of claim 1, wherein the substrate includes a solder resist on a surface of the substrate between neighboring substrate pads of the substrate pads.

3. The semiconductor package of claim 2, wherein the solder resist protrudes above a surface of the substrate.

4. The semiconductor package of claim 2, wherein the solder resist is an epoxy-based material.

5. The semiconductor package of claim 2, wherein the solder resist has a thickness from about 10 microns to about 20 microns.

6. The semiconductor package of claim 2, wherein the solder resist and the cavity prevent the solder from spreading across the surface of the substrate from a substrate pad to a neighboring substrate pad of the substrate pads during a reflow of the solder.

7. The semiconductor package of claim 1, wherein the cavity functions as a crack arrest structure to curtail cracks in the substrate and/or solder from propagating.

8. The semiconductor package of claim 1, wherein each cavity in the substrate is located in the dielectric material around a respective edge portion of the substrate pads.

9. The semiconductor package of claim 8, wherein the dielectric material is an Ajinomoto build-up film or a prepreg material.

10. The semiconductor package of claim 1, wherein the substrate is a routable lead frame (RLF) substrate or an embedded trace substrate (ETS).

11. A semiconductor package comprising:
a substrate comprising a dielectric material, substrate pads and a solder resist on a surface of the substrate between neighboring substrate pads of the substrate pads, wherein a cavity in the dielectric material separates the substrate pads; and
a die being coupled to the substrate using a solder, wherein the solder fills a portion of the cavity.

12. The semiconductor package of claim 11, wherein the solder resist protrudes above the surface of the substrate.

13. The semiconductor package of claim 11, wherein the solder resist and the cavity prevent the solder from spreading across the surface of the substrate from a substrate pad to a neighboring substrate pad of the substrate pads during a reflow of the solder.

14. The semiconductor package of claim 11, wherein the cavity functions as a crack arrest structure to curtail cracks in the substrate and/or solder from propagating.

15. The semiconductor package of claim 11, wherein the cavity in the substrate is located in the dielectric material around a respective edge portion of the substrate pads.

16. The semiconductor package of claim 11, wherein the solder resist material is an epoxy-based material and has a thickness from about 10 microns to about 20 microns.

17. The semiconductor package of claim 11, wherein the substrate is a routable lead frame (RLF) substrate or an embedded trace substrate (ETS).

18. A method of fabricating a semiconductor package, comprising:
forming a cavity in a dielectric material of a substrate between substrate pads of the substrate;
positioning a die with respect to the substrate so that solder on the die is coaxial with respect to the substrate pads;
reflowing the solder to cause the solder to partially fill the cavity; and
encapsulating the die and the substrate with a molding material to form the semiconductor package.

19. The method of claim 18, wherein the substrate includes a solder resist on a surface of the substrate between neighboring substrate pads of the substrate pads, wherein the cavity and the solder resist prevent the solder from spreading across a surface of the substrate from a substrate pad to a neighboring substrate pad of the substrate pads during the reflowing.

20. The method of claim 19, wherein the solder resist protrudes above the surface of the substrate.
